(19) United States
(12) Patent Application Publication
(10) Pub. No.: US 2012/0248605 A1
(43) Pub. Date: Oct. 4, 2012

(54) SEMICONDUCTOR DEVICE AND MANUFACTURING METHOD THEREOF

(75) Inventor: Toshihide YAMAGUCHI, Kanagawa (JP)

(73) Assignee: Renesas Electronics Corporation

(21) Appl. No.: 13/404,715

(22) Filed: Feb. 24, 2012

(30) Foreign Application Priority Data
Mar. 28, 2011 (JP) 2011-070645

(51) Int. Cl. H01L 23/498; H01L 21/768

(52) U.S. Cl. 257/738; 438/613; 257/737; 257/E23.069; 257/E23.068; 257/E21.589

(57) ABSTRACT

A semiconductor device includes an electrode (electrode pad), an insulation film (for example, protective resin film) formed over the electrode and having an opening for exposing the electrode. The semiconductor device further includes an under bump metal (UBM layer) formed over the insulation film and connected by way of the opening 5a to the electrode, and a solder ball formed over the under bump metal. In the under bump metal, a thickness A for the first portion situated in the opening above the electrode and the thickness B for the second portion situated in the under bump metal at the periphery of the opening over the insulation film are in a condition: A/B≧1.5, and the opening and the solder ball are in one to one correspondence.

### CROSS-REFERENCE TO RELATED SPECIFICATIONS

The disclosure of Japanese Patent Application No. 2011-70645 filed on Mar. 28, 2011 including the specification, drawings, and abstract is incorporated herein by reference in its entirety.

### BACKGROUND

The present invention relates to a semiconductor device and a manufacturing method thereof.

There is a technique of mounting a semiconductor device having a solder ball over an electrode to a printed circuit board by flip chip bonding. Generally, an under bump metal (UBM) is formed between the solder ball and the electrode. The under bump metal suppresses metal diffusion between the electrode and the solder ball.

Upon mounting such a semiconductor device, the solder ball is melted by heating and then cooled in a state of opposing the solder ball to the electrode on the side of the printed circuit board. That is, heat cycles are generated upon mounting.

Japanese Unexamined Patent Publication No. 2009-212332 describes a semiconductor device of a structure in which multiple polyimide layers are interposed between an under bump metal and an electrode (metal in the uppermost layer in the patent literature), and the polyimide layer is made softer toward the upper layer.

Japanese Unexamined Patent Publication No. 2000-299343 describes a semiconductor device in which a CU wiring pad is buried in a first insulation film, a second insulation film is formed over the first insulation film and the Cu wiring pad, multiple openings are formed in the second insulation film, an under bump metal (UBM) is formed over the second insulating film and over the Cu wiring pad, a solder bump is formed over the UBM, and multiple openings are present below one solder bump.

### SUMMARY

By the way, a lead-free solder for which demand has been grown in recent years as the material for solder balls has a lower ductility compared with that of a lead-containing solder. Accordingly, when a solder ball is formed of the lead-free solder, stress caused upon mounting the semiconductor device becomes more serious compared with the case of using a lead-containing solder.

According to the structures of Japanese Unexamined Patent Publications Nos. 2009-212332 and 2000-299343, when a solder ball is formed of the lead-free solder, while this can provide an effect capable of moderating the progress of fracture in insulation film (for example, polyimide cracks), there has been a room for improving the suppression of generation of fracture.

As described above, there has been a room for the improvement in suppressing the generation of fracture in the insulation film caused by the stress upon mounting the semiconductor device.

The present invention provides a semiconductor device including an electrode, an insulation film formed over the electrode and having an opening for exposing the electrode, an under bump metal formed over the insulation film and connected by way of the opening to the electrode, and a solder ball formed over the under bump metal, in which the thickness A for the first portion situated in the opening above the electrode and the thickness B for a second portion situated at the periphery of the opening over the insulation film are in a condition: A/B≧1.5, and the opening and the solder ball are in one to one correspondence.

According to the semiconductor device, since the thickness of the first portion situated in the opening over the electrode is relatively thick in the under bump metal, reliability against the diffusion of metal, for example, (electromigration) between the electrode and the solder ball can be ensured easily. Specifically, a high reliability can be ensured since the thickness A for the first portion situated in the opening above the electrode is 1.5 times or more the thickness for the second portion situated at the periphery of the opening above the insulation film in the under bump metal. Further, in the under bump metal, since the thickness B for the second portion situated at the periphery of the opening (situated to the outside of the opening) above the insulation film is relatively thin, the second portion can be deformed more easily than the first portion. Specifically, since the thickness B is ⅔ or less of the thickness A, the second portion can be deformed easily. Accordingly, the second portion can absorb, moderate, and disperse the stress propagating to the insulation film therebelow. This can suppress generation of fracture in the insulation film caused by the stress upon mounting a semiconductor device even when the solver ball is formed of a lead-free solder.

Further, since the opening and the solder ball are in one to one correspondence (that is, a solder ball is formed each by one corresponding to each opening), peeling of the under bump metal from the electrode can be suppressed. A material of an insulation film intrudes to a boundary between the electrode and the under bump metal at the periphery in the bonded portion between the electrode and the under bump metal and the bonding strength between the electrode and the under bump metal is sometimes lowered at the portion. The distance along which the material of the insulation film intrudes to the periphery of the bonded portion is substantially identical irrespective of the area of the bonded portion. Therefore, assuming the total area of the bonded portion as identical, the bonding strength is lowered further as the bonding portion is divided into plurality to increase the number of bonded portions, tending to peel the under bump metal from the electrode. Accordingly, by adopting the structure in which the solder balls are formed each by one corresponding to each of the openings, the bonding strength between the electrode and the under the bump metal can be ensured to the utmost level, and peeling thereof can be suppressed. Then, as a result, fracture in the insulation film caused by stress upon mounting the semiconductor device can be suppressed further.

In a word, according to the semiconductor device, even when the solder ball is formed of a lead-free solder, fracture in the insulation film caused by the stress upon mounting the semiconductor device can be suppressed and the reliability against metal diffusion between the electrode and the solder ball can also be ensured easily.

Further, according to one aspect of the present invention, there is provided a method of manufacturing a semiconductor device including: forming an insulation film having an opening for exposing an electrode over the electrode; forming an under bump metal over the insulation film so as to be connected by way of the opening to the electrode; and forming a solder ball over the under bump metal such that the opening and the solder ball are in one to one correspondence, in which the under bump metal is formed in the step of forming the under bump material such that the thickness A for the first portion situated in the opening above the electrode and the thickness B for the second portion situated at the periphery of the opening over the insulation film in the under bump metal are in a condition: A/B≧1.5.

Further, according to another aspect of the present invention, there is provided a semiconductor device including an electrode, an insulation film formed over the electrode and having an opening for exposing the electrode, an under bump metal formed over the insulation film and connected by way of the opening to the electrode, and a conductive pillar portion formed over the under bump metal, in which the thickness A for the first portion situated in the opening above the electrode and the thickness B for a second portion situated at the periphery of the opening over the insulation film are in a condition: A/B≧1.5, and the opening and the conductive pillar portion are in one to one correspondence.

According to the aspects of the invention, generation of fracture in the insulation film caused by the stress upon mounting the semiconductor device can be suppressed.

### BRIEF DESCRIPTION OF THE DRAWINGS

FIG. 1 is a cross sectional view of a semiconductor device according to a preferred embodiment;

FIG. 2 is a cross sectional view of a semiconductor device according to a preferred embodiment;

FIG. 3 is a plan view of a semiconductor device according to a preferred embodiment;

FIG. 4 is a plan view of a semiconductor device according to a preferred embodiment, in which

FIG. 4A shows one example for the arrangement of bumps, and

FIG. 4B shows another example for the arrangement of bumps;

FIG. 5 is a cross sectional view showing a series of steps of a method of manufacturing the semiconductor device according to the preferred embodiment, in which

FIG. 5A is a view showing a step of forming an opening, and

FIG. 5B is a view showing a step succeeding to FIG. 5A;

FIG. 6 is a cross sectional view showing a series of steps of a method of manufacturing the semiconductor device according to the preferred embodiment, in which

FIG. 6A is a view showing a step of forming a UBM layer in the opening, and

FIG. 6B is a view showing a step succeeding to FIG. 6A;

FIG. 7 is a cross sectional view showing a series of steps of a method of manufacturing the semiconductor device according to the preferred embodiment, in which

FIG. 7A is a view showing an ashing treatment for a resist mask and

FIG. 7B is a view showing a step succeeding to FIG. 7A;

FIG. 8 is a cross sectional view showing a series of steps of a method of manufacturing the semiconductor device according to the preferred embodiment;

FIG. 9 is a cross sectional view showing a series of steps of a method of manufacturing the semiconductor device according to the preferred embodiment;

FIG. 10 is a cross sectional view showing a series of steps of a method of manufacturing the semiconductor device according to the preferred embodiment;

FIG. 11 is a cross sectional view showing a series of steps of a method of manufacturing the semiconductor device according to the preferred embodiment;

FIG. 12 is a graph showing a condition between the thickness for the under bump metal (UBM layer) and generation frequency of white bump,

FIG. 13 is a cross sectional view of a semiconductor device according to a modified embodiment;

FIG. 14 is a cross sectional view of a semiconductor device according to comparative embodiment 1;

FIG. 15 is a plan view and a cross sectional view showing a semiconductor device according to comparative embodiment 2.

### DETAILED DESCRIPTION

Preferred embodiments of the invention are to be described with reference to the drawings. Throughout the drawings, identical constituent elements carry the same references for which explanation may be omitted optionally.

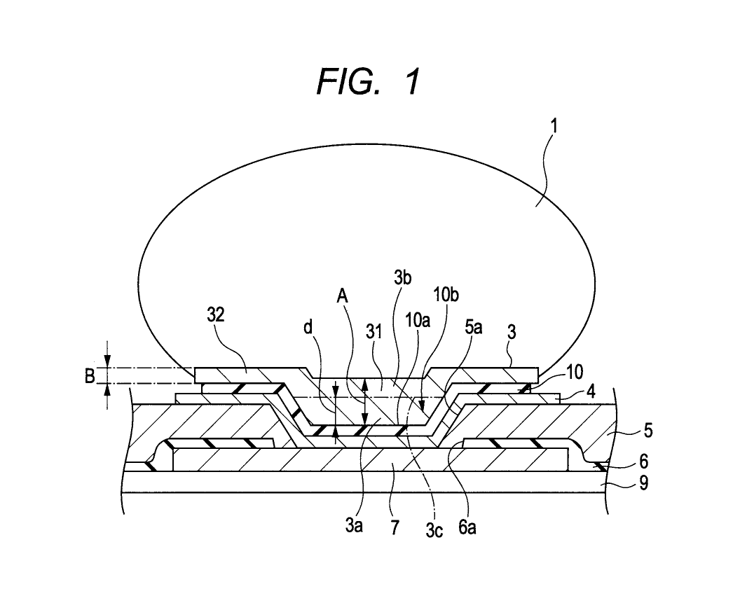

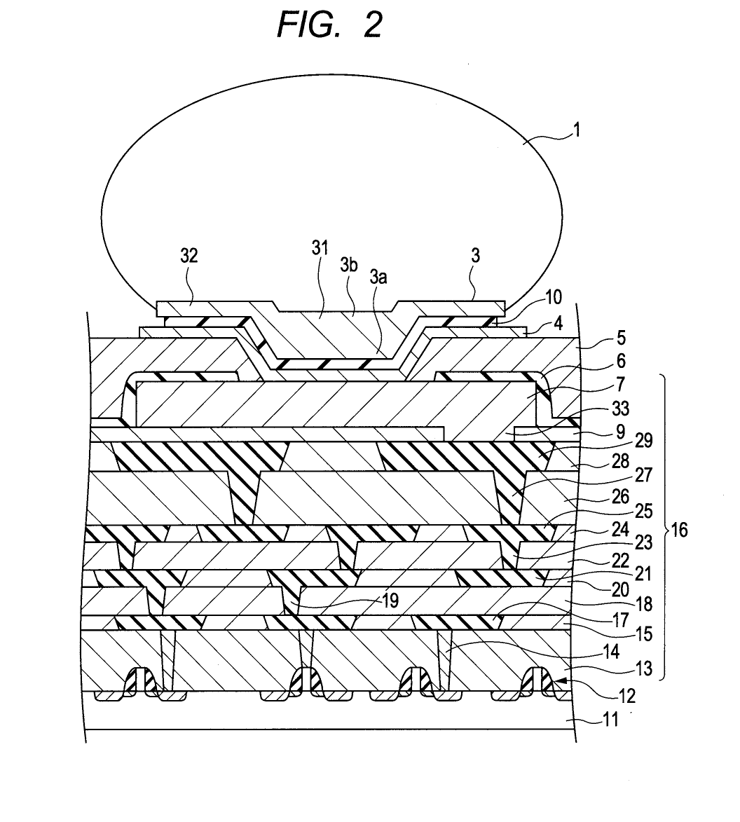

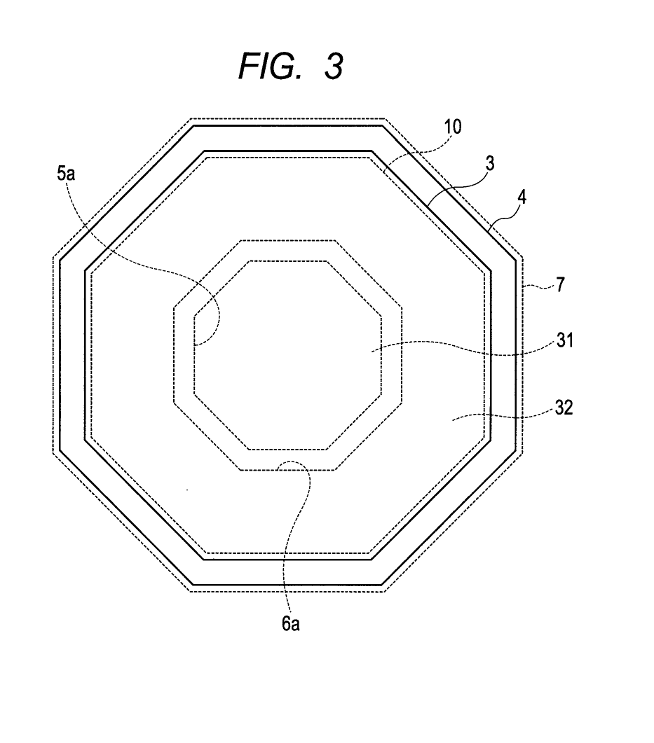

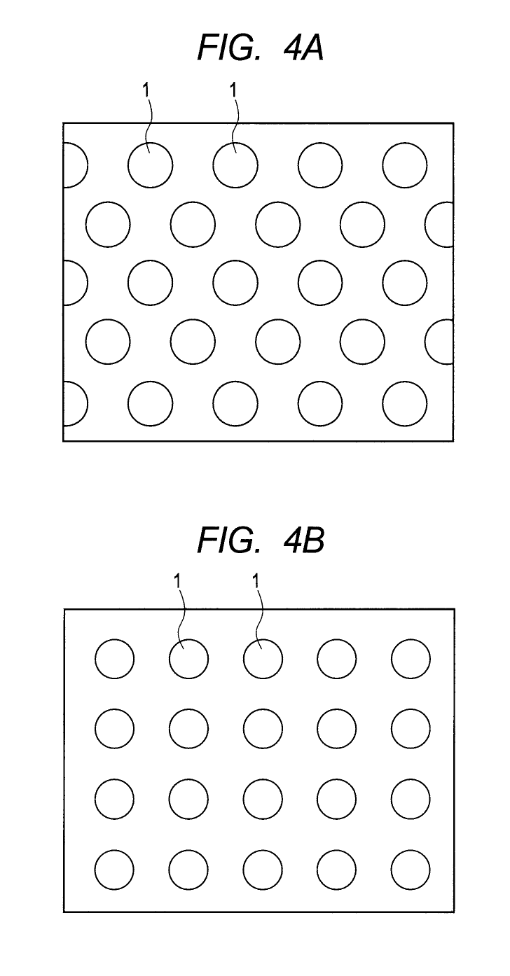

FIG. 1 and FIG. 2 are cross sectional views of a semiconductor device according to a preferred embodiment and FIG. 3 and FIG. 4 are plan views for a semiconductor device according to the preferred embodiment. In FIG. 2, a configuration below the configuration shown in FIG. 1 is also shown. In FIG. 4, a wider region than that in FIG. 3 is shown. A semiconductor device according to the present preferred embodiment includes an electrode (an electrode pad 7), an insulation film (for example, protective resin film 5) formed over the electrode and having an opening 5a for exposing the electrode, an under bump metal (UBM layer 3) formed over the insulation film and connected by way of the opening 5a to the electrode, and a solder ball 1 formed over the under bump metal, in which thickness A for a first portion 31 situated in the opening 5a over the electrode and the thickness B for the second portion 32 situated at the periphery of the opening 5a, satisfy the condition: A/B≧1.5 in the under bump metal, and the opening 5a and the solder ball 1 are in one to one correspondence. The solver ball 1 is formed over one opening 5a. Description is to be made more specifically.

As shown in FIG. 1, the uppermost layer wiring of a semiconductor device includes an electrode pad 7. The uppermost layer wiring is formed over the interlayer insulating film 9 as the uppermost layer of a multi-layered wiring layer 16 (in FIG. 2 to be described later) of the semiconductor device. A protective resin film 5 is formed over the covering nitride film 6 and over the electrode pad in the opening 6a, and an opening 5a for exposing the electrode pad 7 is formed in protective resin film. A covering nitride film 6 is formed over the uppermost layer wiring including the electrode pad 7, in which an opening 6a for exposing the electrode pad 7 is formed in the covering nitride film 6. A Ti film 4 as a barrier metal is formed over the protective resin film 5 and over the electrode pad 7 in the opening 5a. A Cu film 10 is formed over the Ti film 4. An UBM layer 3 is formed over the Cu film 10.

The UBM layer 3 is, for example, an Ni layer. The UBM layer 3 has a first portion 31 as a portion situated in the opening 5a above the electrode pad 7 and the second portion 32 as a portion situated at the periphery of the opening 5a over the protective resin film 5.

The thickness A for the first portion 31 and the thickness B for the second portion 32 satisfy the condition: A/B≧1.5. The opening 5a is formed, for example, in a tapered shape diametrically enlarging upward. Further, the shape of the Ti film 4 and the Cu film 10 reflects the shape of the opening 5a and has a concave portion corresponding to the opening 5a. The concave portion is in a tapered shape diametrically enlarging upward. The first portion 31 is a portion situated inside the opening 5a in a plan view (for example, inside of the upper end of the opening 5a) in the UBM layer 3. Then, the thickness A is a thickness for the portion of the first portion 31 in contact with a bottom 10a of the concave portion 10b of the Cu film 10 in the opening 5a. The second portion 32 is a portion situated at the periphery of the opening 5a (for example, outside of upper end of the opening 5a) in a plan view in the UBM layer 3.

By satisfying the condition: A/B≧1.5, metal diffusion between the solder ball and the electrode pad 7 (for example, EM (electromigration) from the electrode pad 7 to the solder ball 1) can be suppressed preferably by the first portion 31, and the stress propagating to the insulation film therebelow (protective resin film 5 and, thus, an insulation film further therebelow) can be absorbed, moderated, and dispersed by the second portion 32. As a result, occurrence of defects referred to as white bump or the like can be suppressed.

More specifically, the thickness A for the first portion 31 is preferably 2 μm or more. With such a thickness, metal diffusion between the solder ball 1 and the electrode pad 7 can be suppressed more reliably.

Further, the thickness B for the second portion 32 is preferably 1 μm or more. With such a thickness, the second portion 32 can be deposited stably. In other words, since it is difficult to thinly form the under bump metal to less than 1 μm in view of the current process, the thickness B is preferably 1 μm or more.

Further, the thickness B is preferably 2 μm or less. More preferably, the thickness B is less than 2 μm. With such a thickness, the stress can be absorbed, moderated, and dispersed more reliably by the second portion 32.

In the UBM layer 3, multiple portions in the direction of the thickness are, for example, formed in separate steps respectively. Specifically, in the UBM layer 3, the lower portion 3a and the upper portion 3b are formed in steps different from each other. Whether the plural portions of the UBM layer 3 in the direction of the thickness are formed by separate steps respectively can be discriminated by observing the boundary 3c between each of the portions in the direction of the thickness, because of the reason described below. When the plural portions in the direction of the thickness of the UBM layer 3 are formed by separate steps respectively, since the upper portion is formed after peeling a resist used for forming the lower portion, the surface of the lower portion is roughened (unevenness is formed) upon peeling the resist (to be described specifically later). Then, when the roughened surface (uneven surface) remains at the interface 3c between each of the portions in the direction of the thickness, it can be recognized that the plural portions of the UBM layer in the direction of the thickness have been formed by separate steps respectively even after the manufacture of the semiconductor device.

The ground for defining the condition as: A/B≧1.5 can be explained, for example, as described below. At first, for stably depositing the UBM layer 3, it is desired that the minimum thickness is 1 μm or more. That is, it is desired that 1 μm≦B. Further, for sufficiently absorbing, moderating, and dispersing the strength by the second portion 32, it is desired that the thickness B is 2 μm or less. That is, the condition: 1 μm≦B≦2 μm is preferred. Further, UBM layer 3 is formed, for example, by at first forming a lower portion 3a of the first portion 31 (lower portion 3a of the UBM layer 3) in the opening 5a and then forming the upper portion 3b of the UBM layer 3 (upper portion of the first portion 31 and the second portion 32). Accordingly, for stably depositing the lower portion 3a, it is desired that the thickness d is 1 μm or more. That is, the condition: 1 μm≦d is preferred. According to the condition: 1 μm≦B≦2 μm described above, d/B is defined as: d/2≦d/B≦d. Further, according to the condition: 1 μm≦d described above, 0.5≦d/B. On the other hand, since A=B+d, A/B=1 +d/B. In view of the above, it is preferred that A/B=(1+d/B) (1+0.5)=1.5, that is, A/B 1.5.

The solder ball 1 may be formed of a lead solder or formed of lead-free solder. The lead-free solder includes, for example, an Sn—Ag solder or an Sn—Ag—Cu solder. The opening 5a and the solder ball 1 are in one to one correspondence. That is, the solver ball 1 is formed each by one corresponding to each of the openings 5a. Further, a conductive pillar portion may be used as a pillar bump instead of the solder ball 1. The conductive pillar portion may be formed of cupper. In the case of the copper pillar bump, since the ductility thereof is lower than that of the lead-containing solder ball, the stress strain upon mounting the semiconductor device increases to cause fracture in the insulation film in the same manner as in the solder ball of the lead-free solder. In this embodiment, since the stress strain in the bump can be suppressed, occurrence of fracture in the semiconductor device can be effectively suppressed also in the pillar bump.

Then, a configuration below the uppermost layer wiring is to be described with reference to FIG. 2.

A transistor 12 is formed over a substrate 11 such as a silicon substrate, and an interlayer insulation film 13 at the lowermost layer is formed over the substrate 11 so as to cover the transistor 12. The interlayer insulation film 13 is formed, for example, of SiO₂. A contact 14 is buried in the interlayer insulation film 13.

A wiring layer insulation film 15 is formed over the interlayer insulation film 13, and a wiring 17 at the lowermost layer in a multi-layered wiring layer 16 is buried. The transistor 12 is electrically connected by way of the contact 14 to the wiring 17 in the lowermost layer of the multi-layered wiring layer 16.

An interlayer insulation film 18 is formed over the wiring layer insulation film 15 and a via 19 is buried in the interlayer insulation film 18. A wiring layer insulation film 20 is formed over the interlayer insulation film 18 and a wiring 21 is buried in the wiring layer insulation film 20. An interlayer insulation film 22 is formed over the wiring layer insulation film 20 and a via 23 is buried in the interlayer insulation film 22. A wiring layer insulation film 24 is formed over the interlayer insulation film 22 and a wiring 25 is buried in the wiring layer insulation film 24. An interlayer insulation film 26 is formed over the wiring layer insulation film 24 and a via 27 is buried in the interlayer insulation film 26. A wiring layer insulation film 28 is formed in the interlayer insulation film 26 and a wiring 29 is buried in the wiring layer insulation film 28. An interlayer insulation film 9 is formed over the wiring layer insulation film 28 and a via 33 is buried in the interlayer insulation film 9. Then, an uppermost layer wiring including the electrode pad 7 is formed over the interlayer insulation film 9.

The uppermost layer wiring (including the electrode pad 7) and the via 33 in the uppermost layer are formed, for example, of Al and other wirings and vias than described above (wirings 29, 25, 21, 17, and vias 27, 23, and 19) are formed, for example, of Cu. The uppermost layer wiring (including the electrode pad 7) and the via 33 in the uppermost layer may be formed of Cu.

Further, the interlayer insulation films 18 and 22, and the wiring layer insulation films 15, 20, and 24 are preferably formed of a low-k film (low dielectric constant insulation film). The low-k film is used for decreasing the capacitance between the multi-layered wirings that connect semiconductor devices, which means a material having a specific dielectric constant (for example, specific dielectric constant of 3 or lower) lower than that of a silicon oxide film (specific dielectric constant of 3.9 to 4.5). The low-k film may be formed, for example, of porous insulation film. The porous insulation film includes, for example, a material of a silicon oxide film which is made porous for lowering the specific dielectric constant, a HSQ film (Hydrogen Silsesquioxane)), an organic silica film, a SiOC film comprising a material, for example, black diamond™, CORAL™, Aurora™, etc. which is made porous for lowering the specific dielectric constant.

Further, the interlayer insulation films 26, 9, and wiring layer insulation film 28 are formed, for example, of SiO₂. Further, the covering nitride film 6 is formed, for example, of SiON.

Further, the protective resin film 5 is, for example, a polyimide film.

Further, as shown, for example, in FIG. 3, the outer shape of the UBM layer 3, the Cu film 10, the Ti film 4, and the electrode pad 7, as well as the inner peripheral shape of the opening 5a and the opening 6a are each in an octagonal shape respectively (specifically, normal octagonal shape). They are arranged such that the centers thereof agree with each other, and corresponding sides are parallel to each other.

Further, as shown, for example, in FIG. 4A or FIG. 4B, multiple bumps are formed in the semiconductor device. The bump comprises a solder ball 1, the UBM layer 3, the Cu film 10, the Ti film 4, the electrode pad 7, the opening 5a, and the opening 6a therebelow. The bumps are arranged uniformly over the entire surface of the semiconductor device. The arrangement may be in a houndstone check pattern as shown in FIG. 4A or in a normal lattice pattern as shown in FIG. 4B.

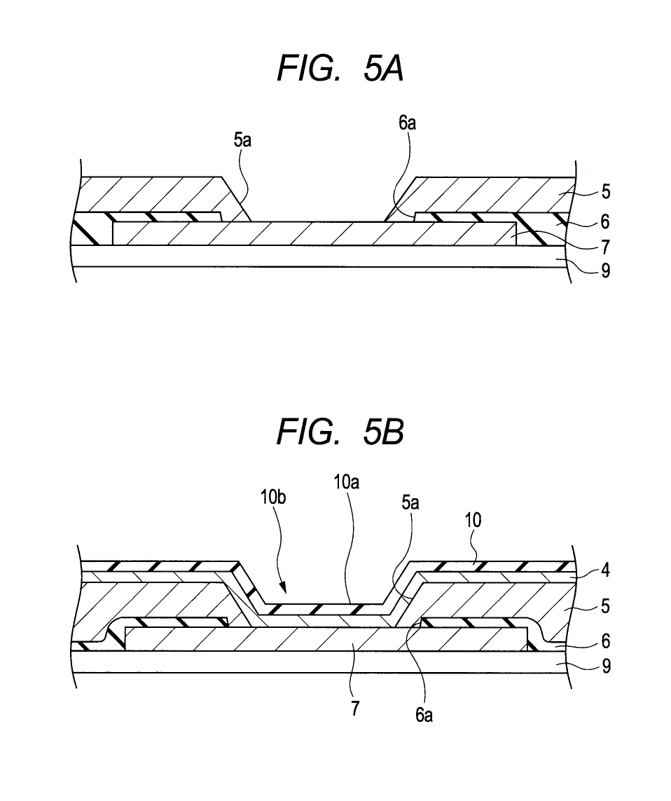

Then, a method of manufacturing a semiconductor device according to this embodiment is to be described. FIG. 5 to FIG. 11 are cross sectional views showing a series of steps for explaining the manufacturing method.

The method of manufacturing the semiconductor device according to this embodiment includes a step of forming an insulation film (for example, a protective resin film 5) having an opening 5a over the electrode (electrode pad 7) for exposing an electrode, a step of forming an under bump metal (UBM layer 3) over the insulation film so as to be connected with the electrode by way of the opening 5a, and a step of forming solder ball 1 over the under bump metal such that the opening 5a and the solder ball 1 are in one to one correspondence. In the step of forming the under bump metal, the under bump metal is formed so as to satisfy the condition: A/B≧1.5 where A represents the thickness for the first portion 31 situated over the electrode in the opening 5a, and B represents the thickness for the second portion 32 situated above the insulation film at the periphery of the opening 5a in the under bump metal. This is to be described specifically below.

At first, the transistor 12 is formed over the substrate 11 by a general semiconductor production process and, further, the multi-layered wiring layer 16 of the configuration described above is formed over the transistor 12. The wiring at the uppermost layer of the multi-layered wiring layer 16 includes the electrode pad 7. A covering a nitride film 6 is formed over the electrode pad 7, and an opening 6a for exposing the electrode pad 7 is formed in the covering nitride film 6. Further, a protective resin film 5 is formed over the electrode pad 7 and the covering nitride film 6, and an opening 5a for exposing the electrode pad 7 is formed also in the protective resin film 5 (FIG. 5A).

Then, a Ti film 4 as a barrier film is deposited over the electrode pad 7 and over the protective resin film 5 by sputtering or the like. Further, a Cu film 10 is deposited over the Ti film 4 by sputtering or the like (FIG. 5B). When the UBM layer 3 is formed by plating, the Cu film 10 serves as a seed for plating.

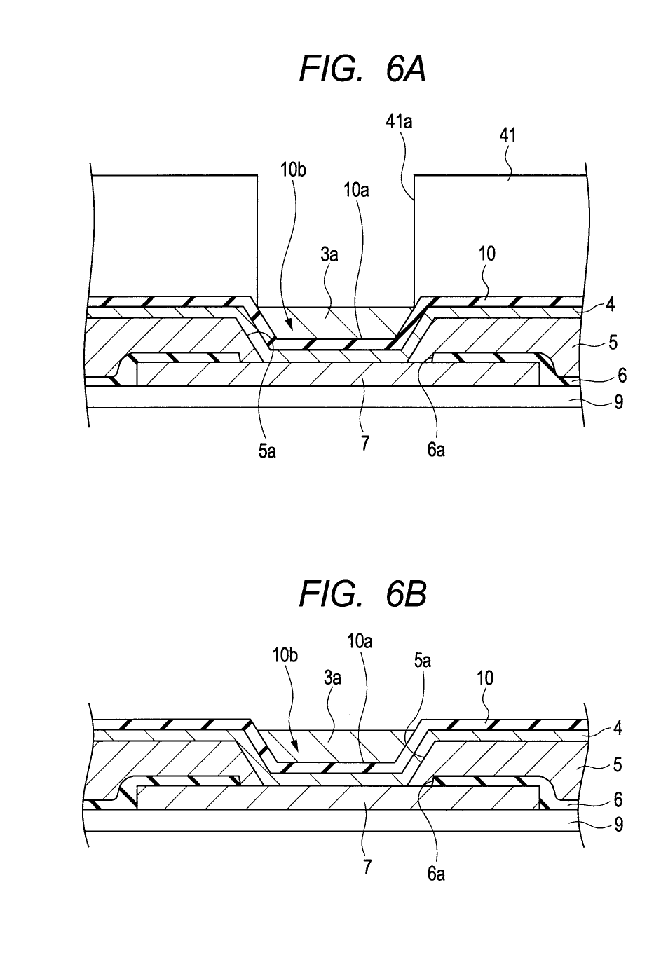

Then, a UBM layer 3 is formed over the Cu film 10. For this step, a resist mask (first mask) 41 is formed at first over the Cu film 10. The resist mask 41 has an opening (first opening) 41a corresponding to the range for forming the lower portion 3a of the UBM layer 3. Then, a lower portion 3a of the UBM layer 3 is formed inside the opening 41a, for example, by plating (electrolytic plating) (FIG. 6A). The lower portion 3a is formed so as to cover the entire region of the bottom 10a of the concave portion 10b of the Cu film 10 in the opening 5a. For this step, the diametrical size of the opening 41a is made larger than that of the bottom 10a, and the opening 41a is positioned such that the entire region of the bottom 10a is contained in the opening 41a. Further, the lower portion 3a is formed, for example, such that it is contained inside the opening 5a in a plan view. More specifically, the lower portion 3a is formed such that it is contained within the concave portion 10b of the Cu film 10. For this purpose, the size and the position of the opening 41a are determined such that the end of the opening 41a is contained within the concave portion 10b of the Cu film 10 in a plan view.

After forming the lower portion 3a of the UBM layer 3, the resist mask 41 is removed (FIG. 6B). For removing the resist mask 41, a peeling solution (for example, developing solution) is used for instance.

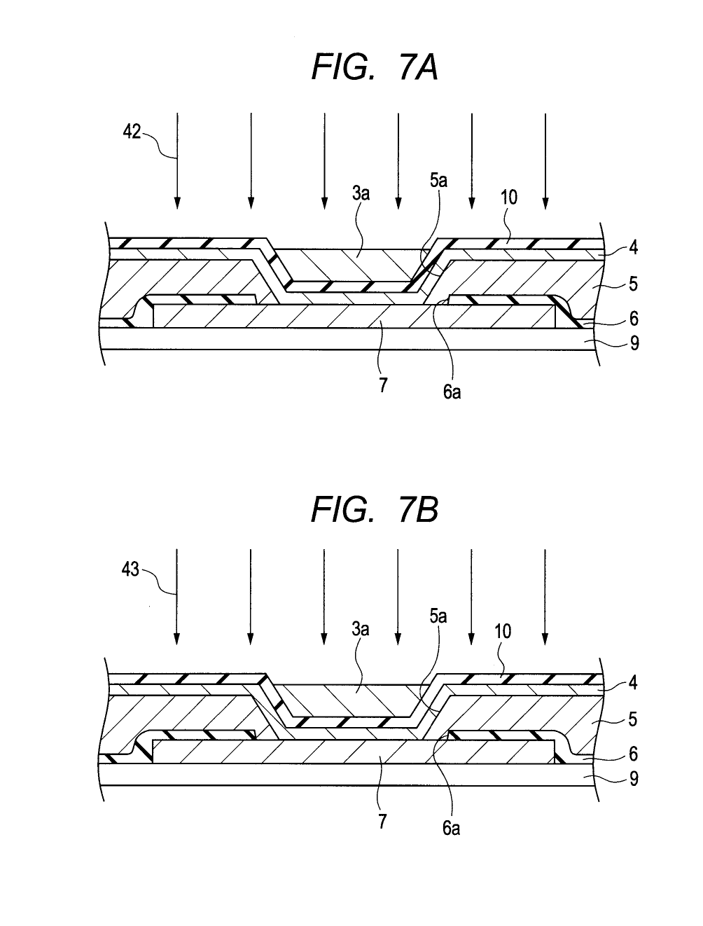

Successively, an ashing treatment 42 is performed for instance (FIG. 7A). The resist mask 41 remaining slightly also after peeling by using the peeling solution is removed by the ashing treatment 42. An oxide layer is sometimes formed on the surface of the lower portion 3a of the UBM layer 3 by the ashing treatment 42. Further, the surface of the lower portion 3a is sometimes roughened to form an uneven surface by the ashing treatment 42.

When the oxide layer formed on the surface of the lower portion 3a by the ashing treatment 42 is thin enough, it is possible to form the upper portion 3b of the UBM layer 3 over the lower portion 3a successively. However, when the oxide layer is thick, a treatment for removing the oxide layer is performed succeeding to the ashing treatment 42. The treatment is, for example, a treatment of removing the oxide layer by a reducing treatment 43 (FIG. 7B). The reducing treatment 43 is, for example, a plasma treatment in a reducing atmosphere (for example, hydrogen plasma treatment). As the treatment for removing the oxide layer, a polishing treatment may also be used. Further, the reducing treatment 43 and the polishing treatment may be used together optionally (they may be performed successively in any sequence).

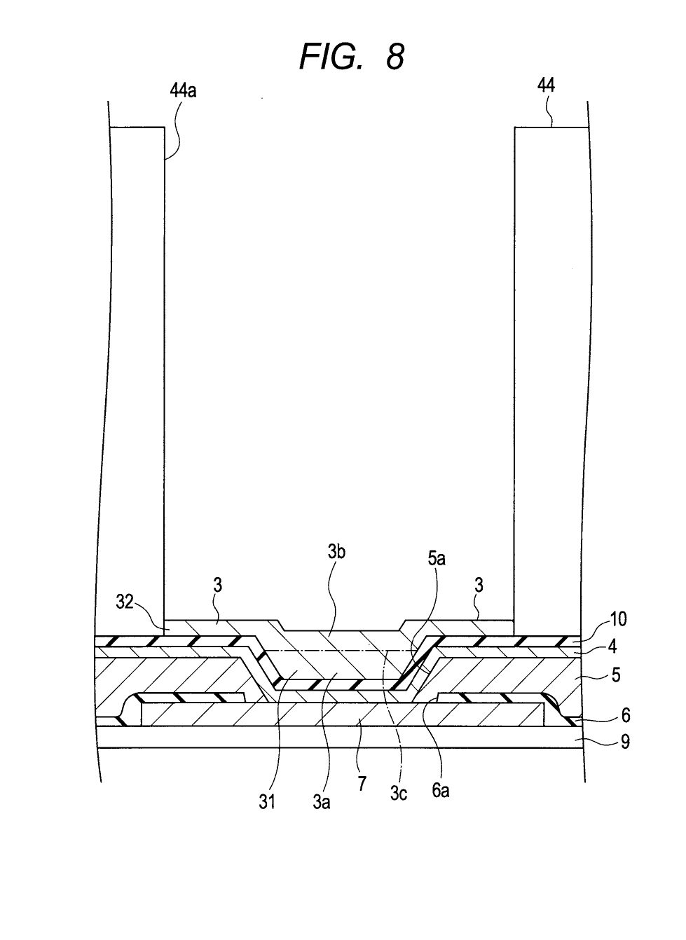

Then, an upper portion 3b of the UBM layer 3 is formed. For this step, a resist mask (second mask) 44 is formed at first over the Cu film 10 as shown in FIG. 8. The resist mask 44 has an opening (second opening) 44a of a shape corresponding to the outer shape of the UBM layer 3 in a plan view. Then, the upper portion 3b of the UBM layer 3 is formed in the opening 44a by a method, for example, of plating (electrolytic plating). That is, the upper portion 3b is formed over the lower portion 3a and over the Cu film 10 at the periphery of the lower portion 3a. Since the upper portion 3b is formed after the step of removing the oxide layer at the upper surface of the lower portion 3a, the upper portion 3b can be formed preferably over the lower portion 3a even when a thick oxide film is formed on the upper surface of the lower portion 3a before removing the oxide layer, and bonding strength between the upper portion 3b and the lower portion 3a can be ensured sufficiently.

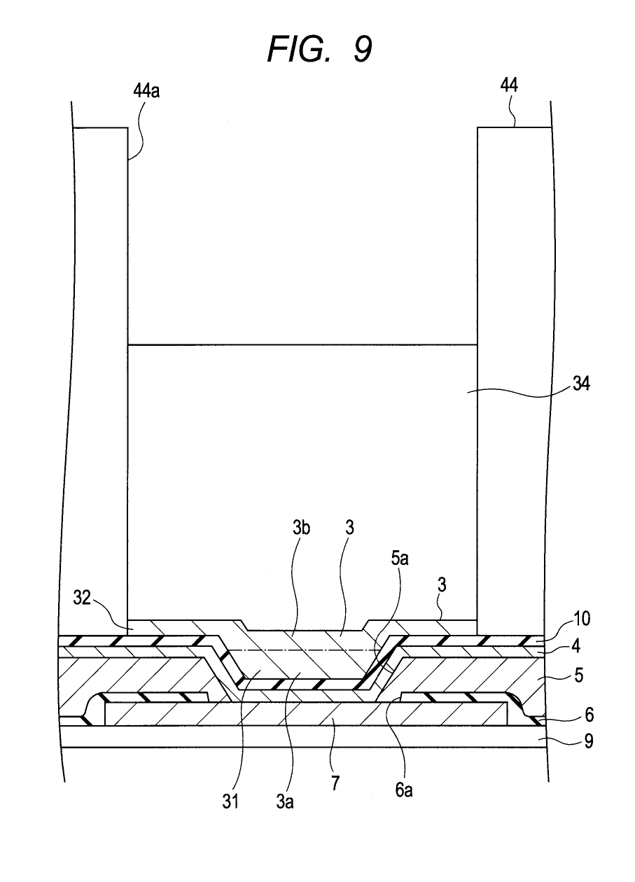

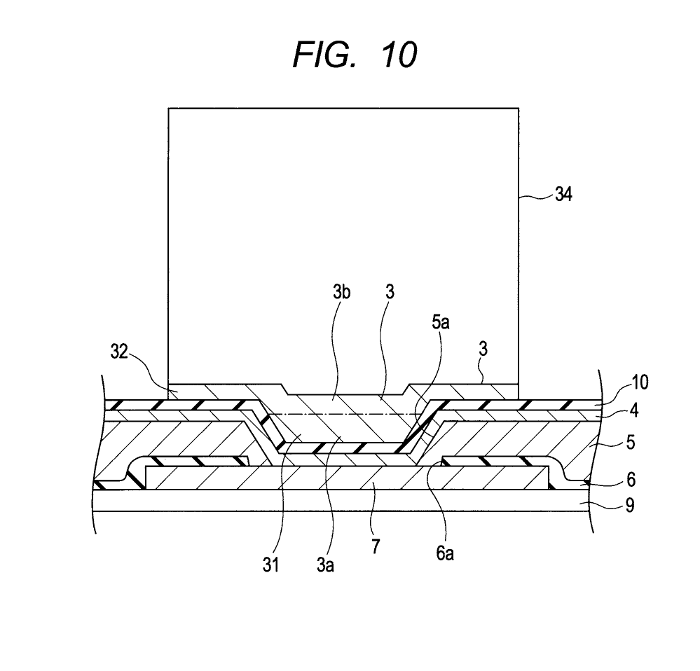

Then, as shown in FIG. 9, a solder layer 34 is formed over the UBM layer 3 by plating (electrolytic plating). That is, the solder layer 34 is formed in the opening 44a of the resist mask 44 by plating (electrolytic plating). Then, the resist mask 44 is removed as shown in FIG. 10.

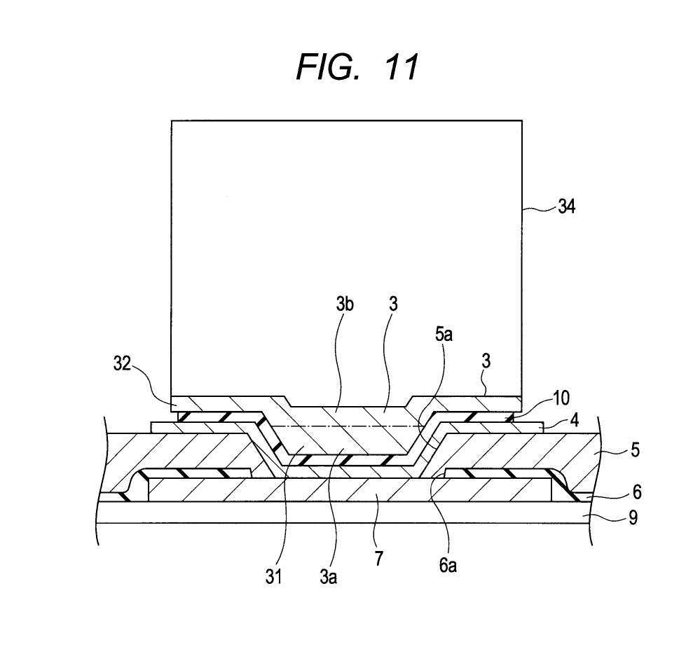

Then, as shown in FIG. 11, the Cu film 10 and the Ti film 4 exposed to the outside of the solder layer 34 (exposed to the outside of the UBM layer 3) are removed by performing entire surface wet etching.

Then, the solder ball 1 is formed by heating to reflow the solder layer 34 (FIG. 1). Thus, the semiconductor device according to this embodiment is obtained.

The semiconductor device is mounted by way of the solder ball 1 to a mounting substrate. The mounting substrate is, for example, a build-up substrate comprising a flat core material situated at a center and Cu wiring layers stacked on the surface and the rearface of the core material each by plural layers (for example, each by the number of layers identical to each other). The core material has physical property values, for example, a modulus of elasticity/4.54 (GPa), a linear expansion coefficient/55 (ppm/° C.), and Poisson ratio/0.36.

Then, a semiconductor device according to a comparative example is to be described.

FIG. 14 is a cross sectional view of a semiconductor device according to a comparative embodiment 1. As shown in FIG. 14, the semiconductor device according to the comparative embodiment 1 is different from the semiconductor device of the preferred embodiment of the invention described above in that a UBM layer 3 is formed at a substantially uniform thickness over the entire surface. The minimum thickness for the central portion of the UBM layer 3 is determined depending on the requirement of suppressing the metal diffusion. The thickness for the periphery of the UBM layer 3, that is, the thickness for the portion situated at the outside of the opening 5a and above the protective resin film 5 is identical with that in the central portion. In the comparative embodiment 1, the UBM layer 3 is formed in one step different from the preferred embodiment of the invention described above. The semiconductor device according to the comparative embodiment 1 is configured in the same manner as the semiconductor device according to the preferred embodiment with respect to other matters.

The stress attributable to the difference of the linear expansion coefficient between the semiconductor device and the mounting substrate is concentrated to the periphery of the UBM layer 3 in the course of cooling after reflowing the solder ball 1 and mounting the semiconductor device to the mounting device. The reason is that it is difficult to sufficiently absorb, moderate, and disperse the stress by the periphery of the UBM layer 3 since the thickness of the UBM layer 3 is uniform over the entire surface and the thickness of the periphery of the UBM layer 3 is identical with that in the central portion. Therefore, as shown in FIG. 14, fracture 35 may be caused in the protective resin film 5 in the portion situated just below the periphery of the UBM layer 3, or fracture 36 may be caused to the portion of a solder ball 1 situated above the periphery of the UBM layer 3. Further, being triggered by the fracture 35 formed in the protective resin film 5, fracture may be sometimes caused also to a low-k film in the lower layers (interlayer insulation films 18, 22, wiring layer insulation films 15, 20, 24: refer to FIG. 2). Fracture in the lower layer wiring can be observed by SAT (Scanning Acoustic Tomograph) and this is referred to as white bump or white spot.

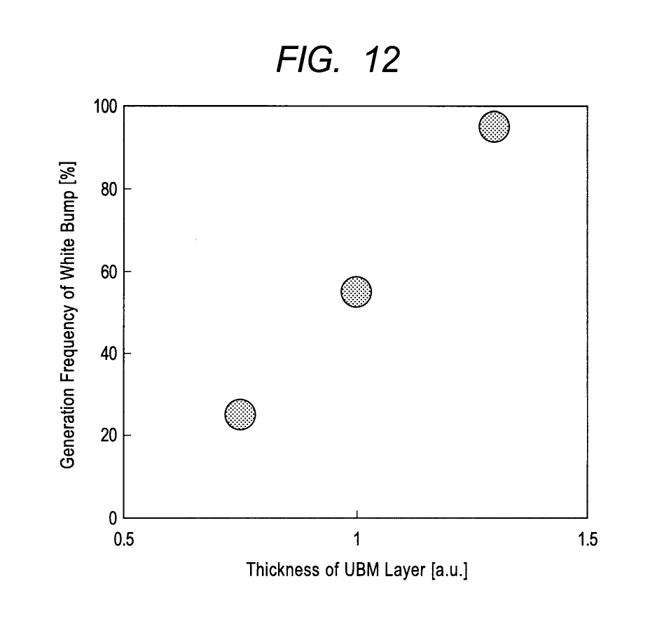

FIG. 12 is a graph showing a condition between the thickness of the UBM layer 3 and the frequency of occurrence of the white bump. The result of FIG. 12 was obtained by examining the situation for the occurrence of the white bump when a semiconductor device having the entire uniform thickness for the UBM layer 3 as shown in FIG. 14 is mounted on a mounting substrate. As the mounting substrate, a build-up substrate comprising a core material and Cu wiring layers stacked above and below the core as the center each by an identical number of layers was used. The core material has physical property values such as a modulus of elasticity/4.54 (GPa), a linear expansion coefficient/55 (ppm/° C.)m, and a Poisson ratio/0.36. A semiconductor chip of a rectangular shape having 14 mm side was used. The number of samples used for the evaluation of each film thickness was 20 chips. As can be seen from FIG. 12, white bumps tend to occur more frequently as the thickness of the UBM layer 3 is larger. This result also means that the white bumps tend to occur more frequently as the thickness increases in the portion of the UBM layer 3 situated at the periphery of the opening 5a and above the protective resin film 5.

Use of lead, mercury, cadmium, etc. for electronic equipment has been inhibited in principle in recent years in the European Union, and it is demanded to transit the solder ball 1 from the lead solder to the lead-free solder. Since the lead solder has high ductility, it has a high performance of absorbing stress, whereas the lead-free solder has lower ductility than the lead solder and it has lower performance of absorbing stress. Accordingly, the fracture of the film or that in the ball 1 tends to occur more frequently. Fracture in the interlayer insulation film is caused remarkably when the interlayer insulation film comprises a low-k film.

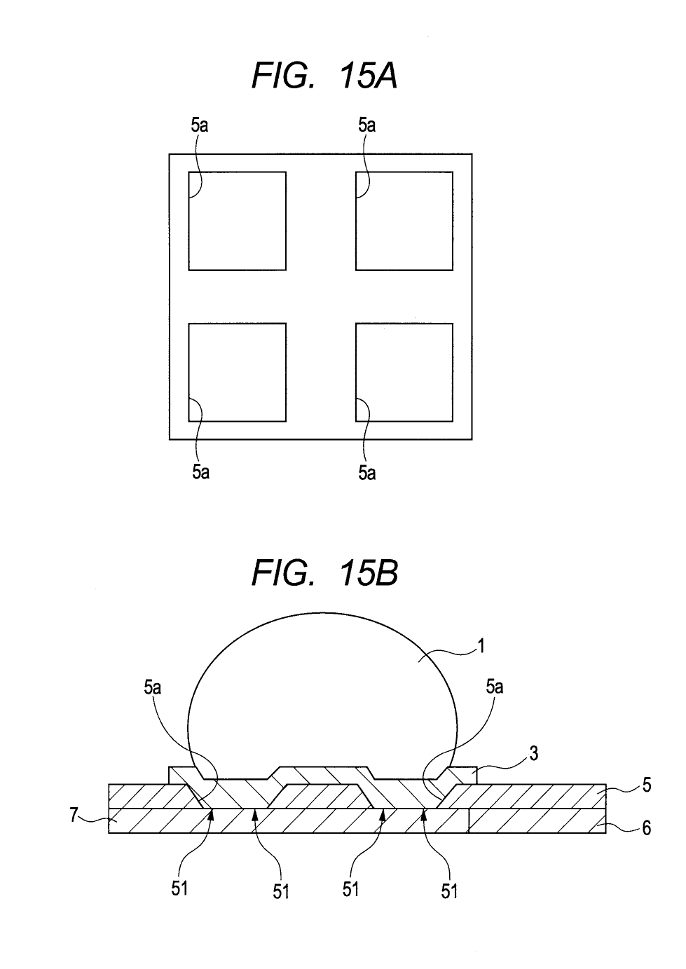

FIG. 15A is a plan view showing the arrangement of openings 5a in a semiconductor device according to a comparative embodiment 2 and FIG. 15B is a cross sectional view of the semiconductor device according to the comparative embodiment 2. As shown in FIG. 15, in the semiconductor device according to the comparative embodiment 2, four openings 5a are formed corresponding to one ball 1. A UBM layer 3 is connected by way of the four openings 5a to an electrode pad 7 and the solder ball 1 is formed over the UBM layer 3.

In the case of the comparative embodiment 2, the UBM layer 3 tends to be peeled from the electrode pad 7. This is because a material that forms a protective resin film 5 (for example, polyimide) sometimes intrudes to the boundary between the electrode pad 7 and the UBM layer 3 at the periphery 51 (FIG. 15B) in the bonded portion between the electrode pad 7 and the UBM layer 3, to lower the bonding strength between the electrode pad 7 and UBM layer 3 at that portion. The distance along which the material of the insulation film intrudes to the periphery 51 of the bonded portion is substantially identical irrespective of the area of the bonded portion. Accordingly, assuming the total area of the bonded portion as identical, the bonding strength is lowered as the bonded portion is divided into plurality to increase the number of the bonded portions, tending to cause peeling of the UBM layer 3 from the electrode pad 7. That is, in a structure where a plurality (for example, four) of openings 5a are formed corresponding to one solder ball 1 as shown in FIG. 15, the bonding strength between the electrode pad 7 and the UBM layer 3 is lowered further tending to cause peeling compared with the preferred embodiment of the invention.

On the contrary, the preferred embodiment of the invention can provide the following effects.

Since the thickness A for the first portion 31 situated in the opening 5a above the electrode pad 7 is made relatively thick in the UBM layer 3, reliability against metal diffusion between the electrode pad 7 and the solder ball 1 (for example, by EM (electromigration)) can be ensured easily. Specifically, a high reliability can be ensured when the thickness A for the first portion 31 is 1.5 times or more the thickness B for the second portion 32 situated at the periphery of the opening 5a over the protective resin film 5. For example, the EM standard value per one bump process corresponding to a half-pitch (hp) of 45 nm is about 50 mA in average and, high reliability against EM can be ensured in the semiconductor device according to this embodiment, even when the current flows at the level described above to each of the bumps.

Further, in the UBM layer 3, since the thickness B for the second portion 32 situated at the periphery of the opening 5a (situated to the outside of the opening 5a) over the protective resin film 5 is relatively thin, the second portion 32 can deform more easily than the first portion 31. Specifically, the second portion 32 can deform easily when the thickness B is ⅔ or less of the thickness A. Accordingly, the second portion 32 can absorb, moderate, and disperse the stress that propagates to the insulation film therebelow. That is, the stress transmitted from the periphery of the ball 1 to the protective resin film 5 can be moderated by the UBM layer 3. As a result, occurrence of fracture in the protective resin film 5 can be suppressed. Accordingly, fracture in the low-k film (interlayer insulation films 18, 22, wiring layer insulation films 15, 20, 24: FIG. 2) in the lower layers being triggered from the fracture in the protective resin film 5 can also be suppressed. Further, fracture in the portion situated above the periphery of the UBM layer 3 in the solder ball can also be suppressed. As described above, similar effect can be obtained also in the case of forming the solder ball 1 with a lead-free solder.

Further, since the opening 5a and the ball are in one to one correspondence (that is, each one solder ball 1 is formed corresponding to each of the openings 5a), peeling of the UBM layer 3 from the electrode pad 7 can be suppressed. This is because the bonding strength between the electrode pad 7 and the UBM layer 3 can be ensured to an utmost level by using a configuration in which each one solder ball 1 is formed corresponding to each of the openings 5a. Then, as a result, occurrence of fracture in the insulation film caused by the stress upon mounting the semiconductor device can be suppressed more reliably.

In a word, according to this semiconductor device, even when the solder ball 1 is formed of a lead-free solder, occurrence of fracture in the insulation film caused by the stress upon mounting the semiconductor device can be suppressed, and the reliability against metal diffusion between the electrode pad 7 and the solder ball 1 can also be ensured.

In the structure of Japanese Unexamined Patent Publication No. 2009-212332, since it is necessary to interpose a resin layer between the solder bump and the electrode for moderating the stress and this increases the thickness of the semiconductor device, mounting to the package is difficult. On the contrary, in this preferred embodiment, since the stress upon mounting the semiconductor device can be moderated without adding a layer structure for stress moderation, increase in the thickness of the semiconductor device can be suppressed.

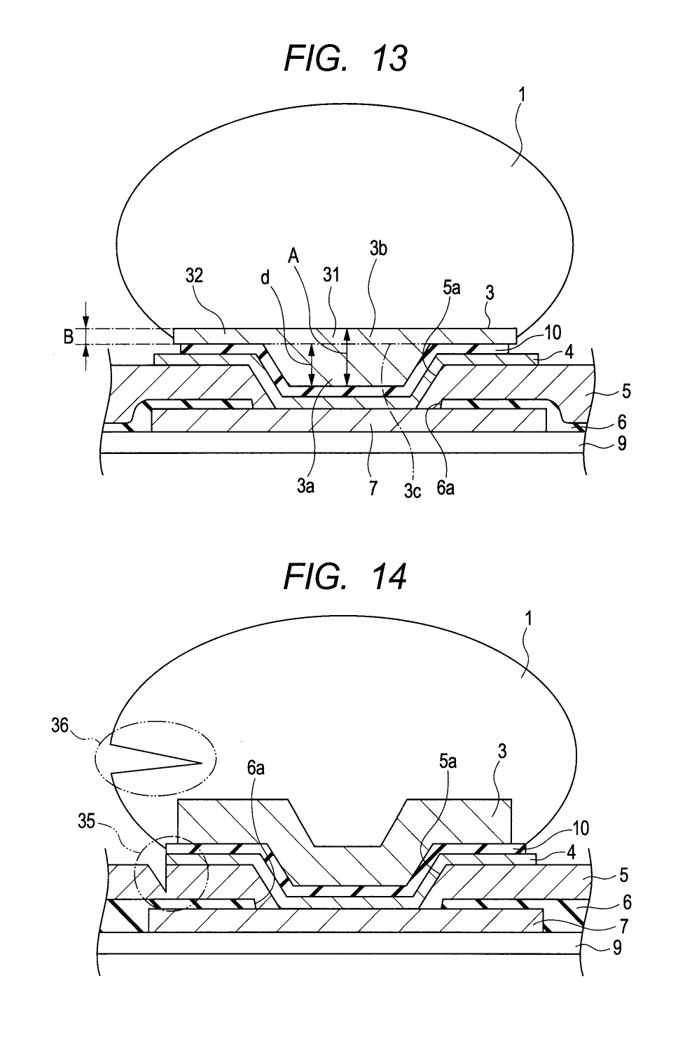

In the preferred embodiment described above, while description has been made to an example in which the height is different between the upper surface at the central area of the first portion 31 and the upper surface of the second portion 32 in the UBM layer 3, the upper surface of the first portion 31 and the upper surface of the second portion 32 may be identical with each other in the UBM layer 3 and the upper surfaces define an identical plane as shown in FIG. 13 (the upper surface of the UBM layer 3 may be flat). In this case, since the upper surface of the UBM layer 3 is flat, stress can be moderated further.

Further, while description has been made for the first embodiment to an example where the solder ball 1 is formed directly on the UBM layer 3 (the solder ball 1 is in contact with the UBM layer 3), a metal film formed of a material (for example, Cu) having a wettability higher than that of the solder (solder ball 1) is formed on the UBM layer 3, and the solver ball 1 may be formed on the metal film.

Further, in the embodiments described above, while description has been made to an example of growing the UBM layer 3 by plating, the UBM layer 3 may be grown also by sputtering.

Further, in the embodiments described above, while description has been made to a case of forming the solder layer 34 by a plating method, the solder layer 34 may be formed also by printing. In this case, a solder layer 34 is formed as shown in FIG. 10 by removing the resist mask 44 after the step in FIG. 8, subsequently disposing a printing plate over the UBM layer 3, and burying the material for the solder layer 34 by using a squeegee into the region for forming the solder layer 34 by way of the printing plate.

What is claimed is:

1. A semiconductor device comprising:
an electrode;
an insulation film formed over the electrode and having an opening for exposing the electrode;
an under bump metal formed over the insulation film and connected by way of the opening to the electrode; and
a solder ball formed over the under bump metal,
wherein the thickness A for the first portion situated in the opening above the electrode and the thickness B for a second portion situated at the periphery of the opening over the insulation film are in a condition: A/B≧1.5, and
wherein the opening and the solder ball are in one to one correspondence.

2. The semiconductor device according to claim 1, wherein the thickness for the first portion is 2 μm or more.

3. The semiconductor device according to claim 1, wherein the thickness for the second portion is 1 μm or more.

4. The semiconductor device according to claim 1, wherein the thickness for the second portion is 2 μm or less.

5. The semiconductor device according to claim 1, wherein the under bump metal comprises a nickel layer.

6. The semiconductor device according to claim 1, wherein the upper surface of the first portion and the upper surface of the second portion define an identical plane.

7. The semiconductor device according to claim 1, wherein the solder ball is a lead-free solder.

8. The semiconductor device according to claim 1, wherein a plurality of portions of the under bump metal in the direction of the thickness are formed by separate steps respectively.

9. A method of manufacturing a semiconductor device comprising:
forming an insulation film having an opening for exposing an electrode over the electrode;
forming an under bump metal over the insulation film so as to be connected by way of the opening to the electrode; and
forming a solder ball over the under bump metal such that the opening and the solder ball are in one to one correspondence,
wherein the under bump metal is formed in the step of forming the under bump material such that the thickness A for the first portion situated in the opening above the electrode and the thickness B for the second portion situated at the periphery of the opening over the insulation film in the under bump metal are in a condition: A/B≧1.5.

10. The method of manufacturing a semiconductor device according to claim 9, wherein the under bump metal is formed by a plating method in the step of forming the under bump metal.

11. The method of manufacturing a semiconductor device according to claim 9, wherein a plurality of portions in the direction of thickness of the under bump metal are formed by separate steps respectively in the step of forming the under bump metal.

12. The method of manufacturing a semiconductor device according to claim 11, wherein the step of forming a portion of the under bump metal in the opening and the step of forming the remaining portion of the under bump metal at the periphery of the opening over the insulation film are performed in this order in the step of forming the under bump metal.

13. The method of manufacturing a semiconductor device according to claim 12, wherein in the step of forming the portion of the under bump metal, the method performs the following steps in this order:
forming a first mask having a first opening corresponding to a range for forming the portion;
forming the portion in the first opening portion by a plating method;
removing the first mask;
forming a second mask having a second opening portion corresponding to the outer shape of the under bump metal in a plan view;
forming the remaining portion of the under bump metal in the second opening portion by a plating method; and
removing the second mask.

14. The method of manufacturing a semiconductor device according to claim 13, wherein in the step of removing the first mask, the method performs the following steps in this order:
peeling the first mask by using a peeling solution;
performing an ashing treatment to the portion of the under bump metal; and
removing an oxide layer formed on the surface of the first portion of the under bump metal by the ashing treatment.

15. The method of manufacturing a semiconductor device according to claim 14, wherein the step of removing the oxide layer includes a step of removing the oxide layer by reduction.

16. The method of manufacturing a semiconductor device according to claim 15, wherein the step of removing the oxide layer by reduction includes a plasma treatment in a reducing atmosphere.

17. The method of manufacturing a semiconductor device according to claim 14, wherein the step of removing the oxide layer includes a step of removing the oxide layer by polishing.

18. The semiconductor device according to claim 1, wherein the solder ball is formed over the one opening.

19. A semiconductor device comprising:
an electrode;
an insulation film formed over the electrode and having an opening for exposing the electrode;
an under bump metal formed over the insulation film and connected by way of the opening to the electrode; and
a conductive pillar portion formed over the under bump metal,
wherein the thickness A for the first portion situated above the electrode in the opening and the thickness B for a second portion situated at the periphery of the opening over the insulation film are in a condition: A/B≧1.5, and
wherein the opening and the conductive pillar portion are in one to one correspondence.
